(19) United States
(12) Patent Application Publication
(10) Pub. No.: US 2013/0265840 A1
(43) Pub. Date: Oct. 10, 2013

(54) SEMICONDUCTOR DEVICE HAVING AUXILIARY POWER-SUPPLY WIRING

(71) Applicant: ELPIDA MEMORY, INC., Tokyo (JP)

(72) Inventors: Masaki YOSHIMURA, Tokyo (JP); Hisayuki NAGAMINE, Tokyo (JP)

(73) Assignee: ELPIDA MEMORY, INC., Tokyo (JP)

(21) Appl. No.: 13/796,797

(22) Filed: Mar. 12, 2013

(30) Foreign Application Priority Data
Apr. 6, 2012 (JP) 2012-086945

(51) Int. Cl. G06F 1/26; G11C 5/14

(52) U.S. Cl. CPC G06F 1/26; G11C 5/14
USPC 365/226; 327/565

(57) ABSTRACT

Disclosed herein is a semiconductor device that includes a signal wiring arranged on a first layer and extending over the circuit block or blocks in the first direction so as to reach the first circuit block and produce a free space above the first circuit block, the signal wiring being electrically connected to the first circuit block, a power-supply wiring arranged on a second layer and extending over the circuit block or blocks in the first direction so as to reach the first circuit block, the power-supply wiring supplying an operating voltage to the first circuit block and an auxiliary power-supply wiring being configured to enhance the operating voltage supplied by the power supply line, and the auxiliary power-supply wiring being formed in the free space produced by the arrangement of the signal wiring.

### BACKGROUND OF THE INVENTION

1. Field of the Invention

The present invention relates to a semiconductor device, and more particularly to a semiconductor device having an auxiliary power-supply wiring.

2. Description of Related Art

In a semiconductor device that has a plurality of functional blocks, a plurality of power-supply wiring are provided to supply operating power voltage to the functional blocks in addition to a signal wiring that is used to transmit and receive signals between the functional blocks. It is desirable that a potential that is supplied by the power-supply wiring be constant at any location on a chip. However, at a location that is distant from a power-supply circuit, the potential may decline. To mitigate such a phenomenon, what is disclosed in Japanese Patent Application Laid-Open No. 2004-273844 is a method of enhancing the power supply by forming the power-supply wirings into a mesh pattern.

However, in order to form the power-supply wirings into a mesh pattern, sufficient free space is required for wiring tracks. If there is not sufficient free space on wiring tracks, the size of the chip needs to be increased to form the power-supply wirings into a mesh pattern. Against such a background, a technique for enhancing the power supply without increasing the size of the chip is desired.

### SUMMARY

In one embodiment of the present invention, there is provided a semiconductor device that includes: a plurality of circuit blocks arranged in a first direction, the circuit blocks including a first circuit block that is positioned an end of the circuit blocks in the first direction, a signal wiring arranged on a first layer and extending over the circuit block or blocks in the first direction so as to reach the first circuit block and produce a free space above the first circuit block, the signal wiring being electrically connected to the first circuit block, a power-supply wiring arranged on a second layer and extending over the circuit block or blocks in the first direction so as to reach the first circuit block, the power-supply wiring supplying an operating voltage to the first circuit block, and an auxiliary power-supply wiring being configured to enhance the operating voltage supplied by the power supply Line, and the auxiliary power -supply wiring being formed in the free space produced by the arrangement of the signal wiring.

In another embodiment of the present invention, there is provided a semiconductor device that includes: first and second circuit blocks arranged in a first direction, first and second wiring tracks each provided on the first and second circuit blocks and each extending in the first direction, a first signal wiring supplying a first signal to the first circuit block, the first signal wiring being provided on the first wiring track on the first circuit block, a first power-supply wiring supplying an operating voltage to the first circuit block, the first power-supply wiring being provided on the second wiring track on the first and second circuit blocks, a first auxiliary power-supply wiring provided on the first wiring track on the second circuit block; and second and third auxiliary power-supply wirings each extending in a second direction that crosses the first direction, the second and third auxiliary power-supply wirings being extending parallel to each other, each of the second and the third auxiliary power-supply wirings being electrically connected between the first power-supply wiring and the first auxiliary power-supply wiring on the second circuit block.

According to the embodiments of the present invention, an auxiliary power-supply wiring is provided in a free space that is positioned on a fine extended from a signal wiring. Therefore, without adding a wiring track, or without increasing the chip size, a power supply can be enhanced.

### BRIEF DESCRIPTION OF THE DRAWINGS

FIG. 1 is a block diagram showing an entire configuration of a semiconductor device according to a first embodiment of the present invention;

FIG. 2 is a schematic plane view illustrating a layout of the semiconductor device according to the first embodiment of the present invention;

FIG. 3 is a diagram showing in more detail a region A shown in FIG. 2;

FIG. 4 is a circuit diagram showing a main part of the memory cell array;

FIG. 5 is a diagram showing in more detail a region B shown in FIG. 3;

FIG. 6 is an X-direction cross-sectional view illustrating a multilayer wiring structure on the memory cell array;

FIG. 7 is a diagram showing in more detail a region C shown in FIG. 5 according to the first embodiment of the present invention;

FIG. 8 is a diagram showing wirings connected to a column decoder according to a second embodiment of the present invention;

FIG. 9 is a diagram showing wirings connected to the column decoder and a main amplifier;

FIG. 10 is a diagram showing wirings connected to a row decoder according to a third embodiment of the present invention; and

FIG. 11 shows an example of a wiring layout of power-supply wirings and auxiliary power-supply wirings according to a fourth embodiment of the present invention.

### DETAILED DESCRIPTION OF THE EMBODIMENTS

Preferred embodiments of the present invention will be explained below in detail with reference to the accompanying drawings. The following detailed description refers to the accompanying drawings that show, by way of illustration, specific aspects and embodiments in which the present invention may be practiced. These embodiments are described in sufficient detail to enable those skilled in the art to practice the present invention. Other embodiments may be utilized, and structure, logical and electrical changes may be made without departing from the scope of the present invention. The various embodiments disclosed herein are not necessarily mutually exclusive, as some disclosed embodiments can be combined with one or more other disclosed embodiments to form new embodiments.

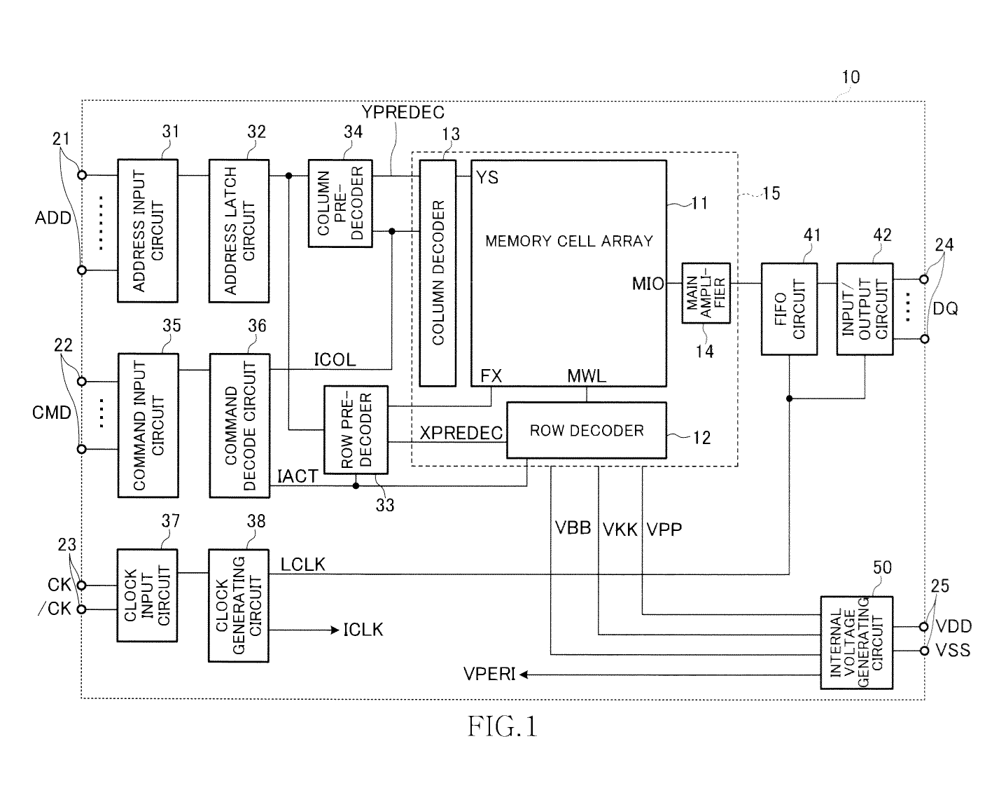

FIG. 1 is a block diagram showing an entire configuration of a semiconductor device 10 according to a first embodiment of the present invention. Referring now to FIG. 1, the semiconductor device 10 is a DRAM (Dynamic Random Access Memory) integrated on a single semiconductor chip. The semiconductor device 10 includes a memory cell array 11. Row access to the memory cell array 11 is carried out by a row decoder 12, and column access by a column decoder 13. A memory cell that is selected by the row access and the column access is connected to a main amplifier 14 via main input/output wirings MIO. While the details will be described later, the memory cell array 11, the row decoder 12, the column decoder 13, and the main amplifier 14 are laid out in a memory cell array region 15.

According to the first embodiment, word lines are hierarchized into main word lines MWL and sub-word lines. The main word lines MWL are selected by the row decoder 12. The sub-word lines are selected by a sub-word selection signal EX, which is generated by a row pre-decoder 33. Bit tines are selected by a column selection signal YS, which is generated by the column decoder 13. Incidentally, in the present specification, a wiring that is used to transmit a signal may be represented by the same reference symbol as that of the signal. For example, a sub-word selection line that is used to transmit a sub-word selection signal FX may be represented by reference symbol FX, and may be referred to as “sub-word selection line FX.” A column selection line that is used to transmit a column selection signal YS may be represented by reference symbol YS, and may be referred to as “column selection line YS.” The same is true for other signals.

As shown in FIG. 1, the semiconductor device 10 employs a plurality of external terminals that include address terminals 21, command terminals 22, clock terminals 23, data terminals 24, and power supply terminals 25.

The address terminals 21 are supplied with an address signal ADD from outside. The address signal ADD supplied to the address terminals 21 is transferred via an address input circuit 31 to an address latch circuit 32 that latches the address signal ADD. The address signal ADD latched in the address latch circuit 32 is supplied to the row pre-decoder 33 and the column pre-decoder 34.

The command terminals 22 are supplied with a command signal CMD from outside. The command signal CMD supplied to the command terminal 22 is transferred via a command input circuit 35 to a command decode circuit 36. The command decode circuit 36 decodes the command signal CMD to generate various internal commands that include an active signal IACT and a column signal ICOL.

The active signal IACT is activated when the command signal CMD indicates a row access (an active command). When the active signal IACT is activated, the address signal ADD latched in the address latch circuit 32 is supplied to the row pre-decoder 33. The row pre-decoder 33 pre-decodes the address signal ADD that is row address to generate row pre-decode signals XPREDEC and sub-word selection signals FX. The row pre-decode signals XPREDEC are supplied to the row decoder 12 to generate the main word signals MWL. In the memory cell array 11, any one of the sub-word lines is selected based on the main word signals MWL and the sub-word selection signals FX.

The column signal ICOL is activated when the command signal CMD indicates a column access (a read command or a write command). When the column signal ICOL is activated, the address signal ADD latched in the address latch circuit 32 is supplied to the column pre-decoder 34. The column pre-decoder 34 pre-decodes the address signal ADD that is column address to generate column pre-decode signals YPREDEC. The column pre-decode signals YPREDEC are supplied to the column decoder 13 to generate the column selection signal YS. In this manner, the bit line BL designated by this address signal ADD is selected accordingly.

Accordingly, when the active command and the read command are issued in this order and a row address and a column address are supplied in synchronism with these commands, read data is read from a memory cell MC designated by these row address and column address. Read data DQ is output to outside from the data terminals 24 via the main amplifier 14, an FIFO circuit 41 and an input/output circuit 42. Meanwhile, when the active command and the write command are issued in this order, a row address and a column address are supplied in synchronism with these commands, and then write data DQ is supplied to the data terminals 24, the write data DQ is supplied via the input/output circuit 42, the FIFO circuit 41 and the main amplifier 14 to the memory cell array 11 and written in the memory cell MC designated by these row address and column address. The FIFO circuit 41 and the input/output circuit 42 are operated in synchronism with an internal clock signal LCLK. The internal cluck signal LCLK is generated by a clock generating circuit 38.

A pair of clock terminals 23 is supplied with external clock signals CK and /CK from outside, respectively. These external clock signals CK and /CK are complementary to each other and then transferred to the clock generating circuit 38 via a clock input circuit 37. The clock generating circuit 38 generates an internal clock signal ICLK and LCLK based on the external clock signals CK and /CK. The internal clock signal ICLK is a basic clock signal within the semiconductor device 10. The internal clock signal ICLK is supplied to circuit blocks such as the address latch circuit 32 and the command decode circuit 36 and define operation timings of these circuit blocks. The internal clock signal LCLK is supplied to the FIFO circuit 41 and the input/output circuit 42 and define operation timings of these circuit 41 and 42.

The power supply terminals 25 are supplied with power supply potentials VDD and VSS. These power supply potentials VDD and VSS are supplied to an internal voltage generating circuit 50. The internal power supply generating circuit 50 generates various internal potentials VPP, VKK, VBB, VPERI, and the like based on the power supply potentials VDD and VSS. At least the internal potentials VPP, VKK and VBB are supplied to the memory cell array region 15. The internal potential VPERI is used in many other circuit blocks.

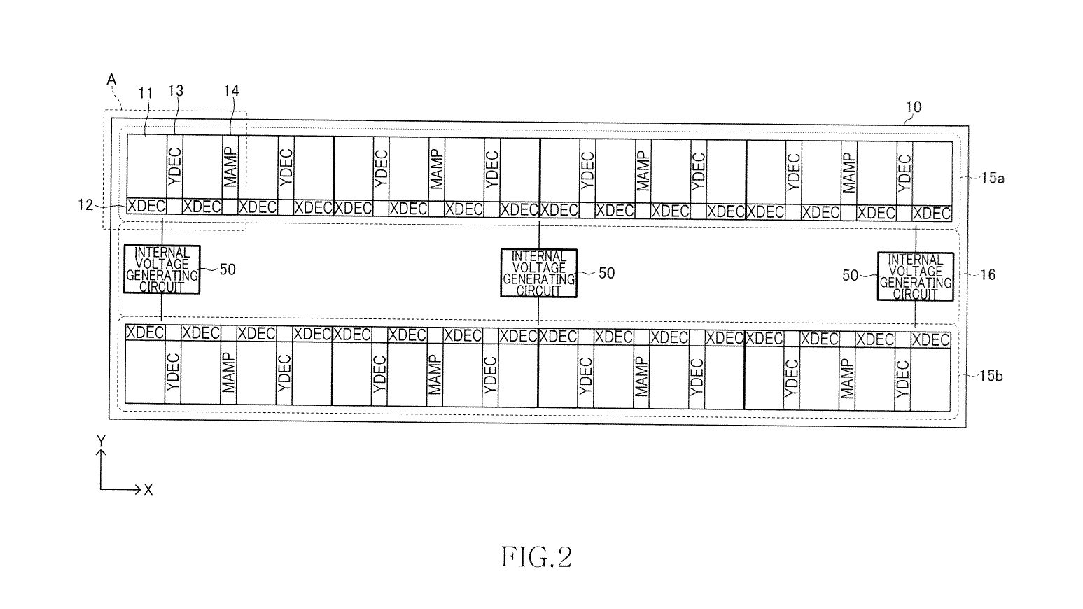

FIG. 2 is a schematic plane view illustrating a layout of the semiconductor device 10. The layout of the semiconductor device 10 will be explained with reference to FIG. 2. Incidentally, FIG. 2 is a diagram that is mainly used to explain the positional relationship of components. The relationship in the magnitude of size between the components, the X-direction scale, the Y-direction scale, and the like are different from those of an actual device. The same is true for the layout charts described later.

As shown in FIG. 2, the semiconductor device 10 of the first embodiment includes two cell array regions 15a and 15b, which extend in an X-direction; and a peripheral circuit region 16, which is positioned between the cell array regions 15a and 15b. The cell array regions 15a and 15b are regions where the memory cell arrays 11, row decoders 12 (XDEC), column decoders 13 (YDEC), main amplifiers 14 (MAMP) shown in FIG. 1 are laid out. The peripheral circuit region 16 is a region where external terminals 21 to 25, and circuits 31 to 38, 41, 42, and 50 are laid out. In this manner, the semiconductor device 10 of the first embodiment has a center-pad structure in which the external terminals 21 to 25 are disposed in a portion that is substantially positioned at the Y-direction center. However, the present invention is not limited to the center-pad structure. The present invention may be an edge-pad structure in which the external terminals are disposed in an edge portion of the chip.

According to the layout shown in FIG. 2, in the peripheral circuit region 16, a plurality of internal power-supply generating circuits 50 are provided to generate various types of internal potential. These internal potentials are supplied to the cell array regions 15a and 15b. Accordingly, the near ends of power-supply wirings that are provided in the cell array regions 15a and 15b are on the peripheral circuit region 16 side, and the far ends on the chip end portion side.

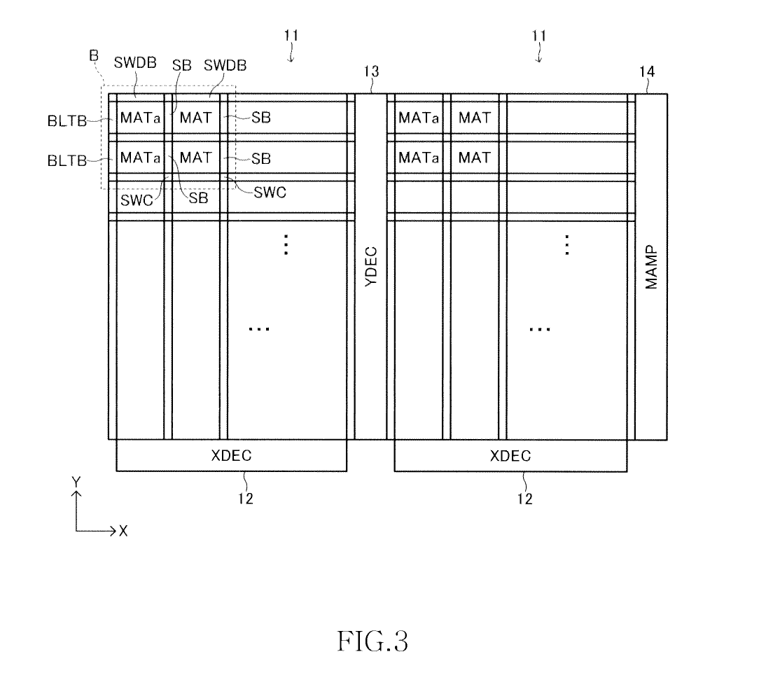

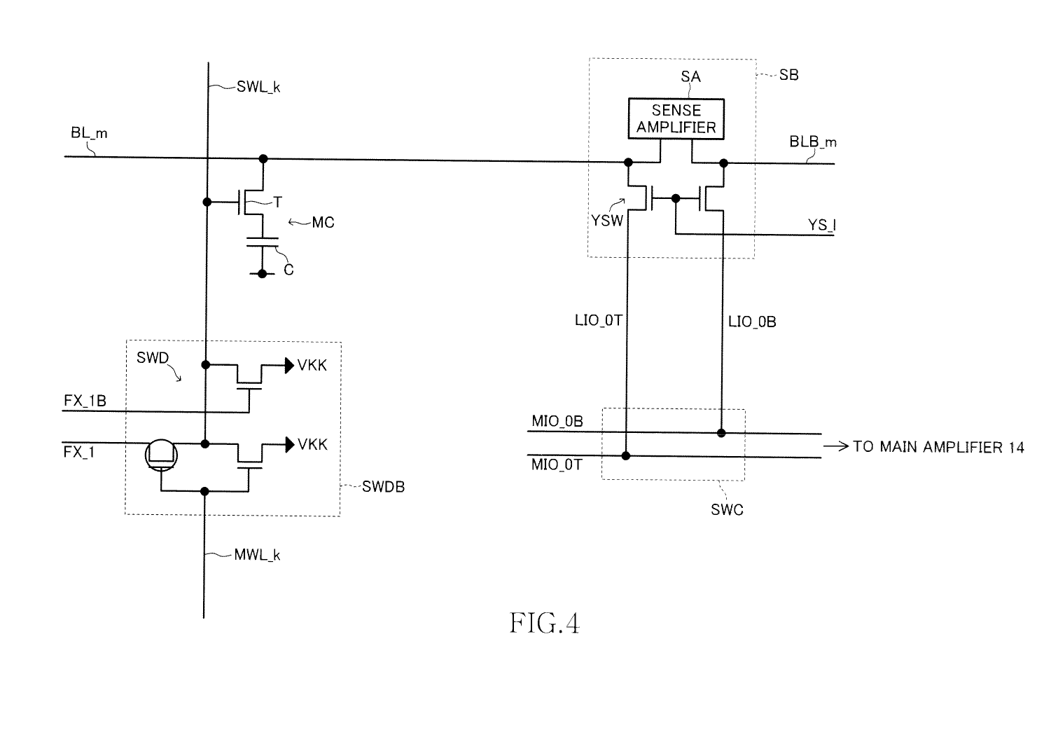

FIG. 3 is a diagram showing in more detail a region A shown in FIG. 2. Turning to FIG. 3, the memory cell array 11 includes a plurality of memory mats MAT that are arranged in a matrix pattern. Each of the memory mats MAT is a region that includes a plurality of sub-word lines, a plurality of bit lines, and a plurality of memory cells disposed at the intersection points of the sub-word line and the bit line. As shown in FIG. 4, a memory cell MC has a structure in which a cell transistor T and a cell capacitor C are connected in series. A gate electrode of the cell transistor T is connected to a corresponding sub-word line SWL_k. A source or drain of the cell transistor T is connected to a corresponding bit line BL_m.

Returning to FIG. 3, on both sides of a memory mat MAT in the Y-direction, sub-word driver blocks SWDB are arranged.

Each of the sub-word driver blocks SWDB is a region where a plurality of sub-word drivers SWD are disposed. The circuit configuration of a sub-word driver SWD is shown in FIG. 4. Based on a main word signal MWLk and sub-word selection signals FX_1 and FX_1B, the sub-word driver SWD drives a corresponding sub-word line SWL_k.

On both sides of a memory mat MAT in the X-direction, sense blocks SB are arranged. Each of the sense blocks SB is a region in which a plurality of sense amplifiers SA are disposed. As shown in FIG. 4, the bit lines BL_m and BLB_m that are paired are connected to one sense amplifier SA. The sense amplifier SA is designed to amplify a difference in potential between the bit lines. To each sense amplifier SA, a column switch YSW is assigned. When a corresponding column selection signal YS_1 becomes activated, the sense amplifier SA is electrically connected to local input/output wirings LIO_0T and LIO_0B that are complementary to each other.

At the positions of four corners when seen from a memory mat MAT, switch circuit regions SWC are arranged. Each of the switch circuit regions SWC is a region where a circuit for connecting the local input/output wiring LIO_0T and LIO_0B and the main input/output wirings MIO_0T and MIO_0B, and the like are disposed. The local input/output wirings LIO may be connected directly to the main input/output wirings MIO as shown in FIG. 4. Alternatively, the local input/output wirings LIO maybe connected to the main input/output wirings MIO via a transfer gate or the like, or via a sub-amplifier having an amplification function.

The semiconductor device 10 of the first embodiment has a so-called open bit line structure. Therefore, bit lines BL that are paired belong to different memory mats MAT, meaning that half of the bit lines of the memory mats MATa that are positioned in the X-direction end portion are dummy bit lines. The dummy bit lines are fixed to a predetermined potential in bit-line termination blocks BLTB shown in FIG. 3.

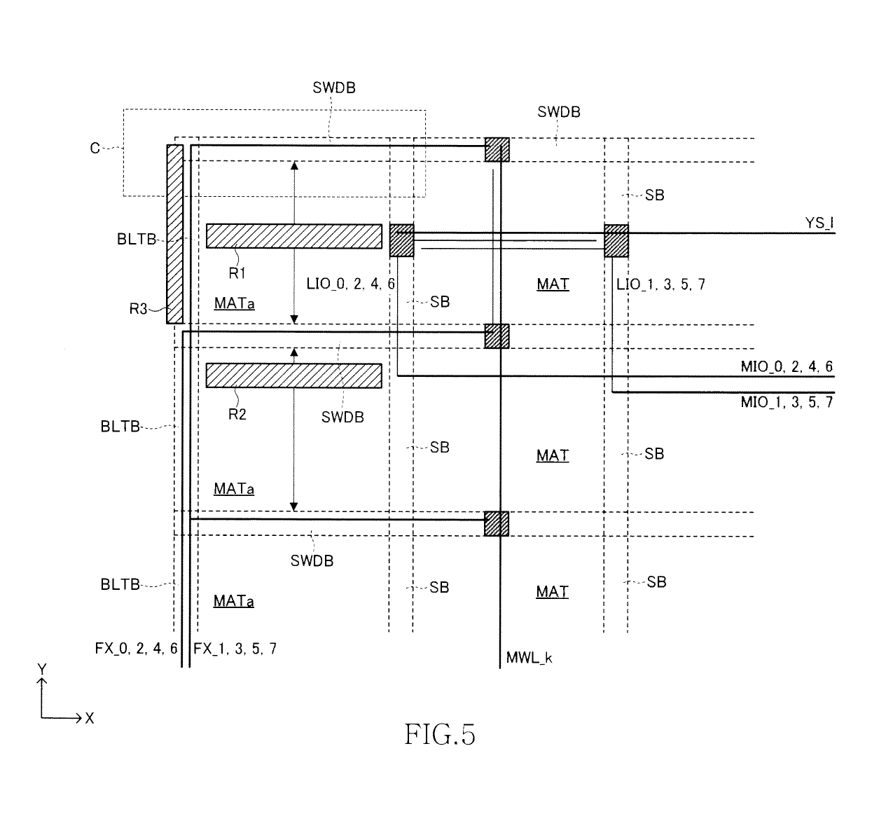

FIG. 5 is a diagram showing in more detail a region B shown in FIG. 3. Turning to FIG. 5, the column selection lines YS and the main input/output wirings MIO are wirings that extend in the X-direction. The main word lines MWL are wirings that extend in the Y-direction. The sub-word selection lines FX includes a portion that extends in the Y-direction, and a portion that extends in the X-direction.

More specifically, the column selection lines YS are so provided as to extend in the X-direction on the memory mats MAT and the sense blocks SB, and are connected to the corresponding column switches YSW in the sense blocks SB. In this case, no column selection lines YS need to be provided on the memory mats MATe, which are positioned in the end portion. The reason is that there are no sense blocks SB in regions beyond the memory mats MATe, which are positioned in the end portion; and that only the bit-line termination blocks BLTB exist in the regions. The above structure means that, on the memory mats MATa positioned in the end portion, free spaces of wiring tracks are generated on X-direction lines that are extended from the column selection lines YS. In FIG. 5, such a free space is denoted by R1. In the case of FIG. 5, the free space R1 that is generated on an extended line of a predetermined column selection line YS_1 is hatched. However, the free spaces R1 emerge across the entire regions of the memory mats MATa.

The main input/output wirings MIO are so provided as to extend in the X-direction on the memory mats MAT and the sense blocks SB, and are connected to the corresponding local input/output wirings LIO in the sense blocks SB. No main input/output wirings MIO need to be provided on the memory mats MATa, which are positioned in the end portion, for the same reason as the column selection lines YS. Accordingly, on the memory mats MATa positioned in the end portion, free spaces of wiring tracks are generated on X-direction lines that are extended from the main input/output wirings MIO. In FIG. 5, such a free space is denoted by R2. In the case of FIG. 5, the free space R2 that is generated on an extended line of a predetermined main input/output line MIO_0, 2, 4, or 6 is hatched. However, the free spaces R2 emerge across the entire regions of the memory mats MATa.

The sub-word selection lines FX are so provided as to extend in the Y-direction on the bit-line termination blocks BLTB, as well as to extend in the X-direct ion on corresponding sub-word driver blocks SWDB. As shown in FIG. 5, the even-numbered sub-word selection lines FX_0, 2, 4, and 6 and the odd-numbered sub-word lines FX_1, 3, 5, and 7 are alternately connected to different sub-word driver blocks SWDB. Therefore, on the bit-line termination blocks BLTB that are positioned in the Y-direction end portion, the odd-numbered sub-word selection lines FX_1, 3, 5, and 7 do not need to be provided. Accordingly, on the bit-line termination blocks BLTB that are positioned in the end portion, free spaces of wiring tracks are generated on Y-direction lines that are extended from the even-numbered sub-word selection lines FX_0, 2, 4, and 6. In FIG. 5, such a free space is denoted by R3. In addition to the above-described wirings, various power-supply wirings are provided on the memory cell array 11.

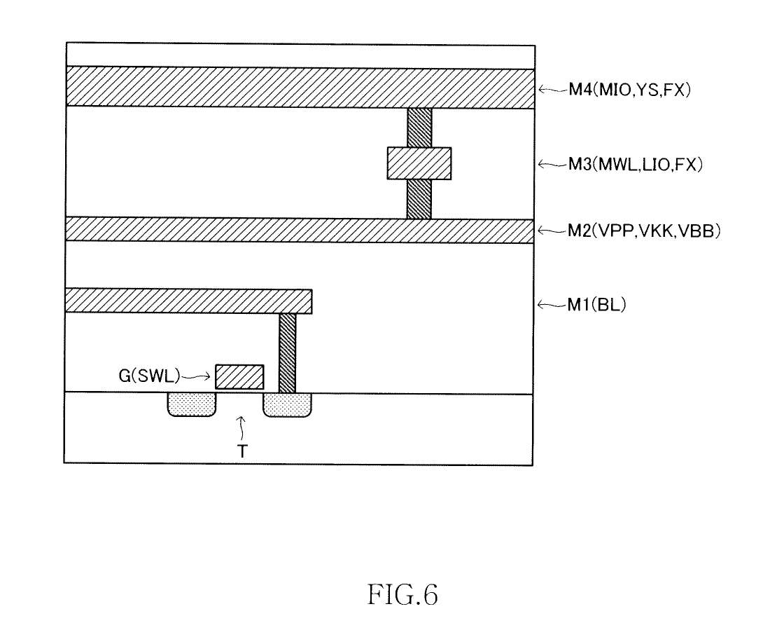

FIG. 6 is an X-direction cross-sectional view illustrating a multilayer wiring structure on the memory cell array 11. In the example shown in FIG. 6, the following are provided: a gate wiring layer G on which a sub-word line SWL is provided; a first metal wiring layer M1 on which a bit line BL is provided; a second metal wiring layer M2 on which a power-supply wiring is provided; a third metal wiring layer M3 on which amain word line MWL, a local input/output wiring LIO, and a sub-word selection line FX are provided; and a fourth metal wiring layer M4 on which a main input/output wiring MIO, a column selection line YS, and a sub-word selection line FX are provided. Among the power-supply wirings provided on the second metal wiring layer M2 are power-supply wirings used for supplying power-supply potentials VPP, VKK, and VBB. As for the wiring resistance of each of the metal wiring layers M1 to M4, the top metal wiring layer M4 has the lowest resistance; the resistance gradually rises toward the bottom layer. The reason is that the cross-sectional area of a wiring on an upper wiring layer is greater than that on a lower layer.

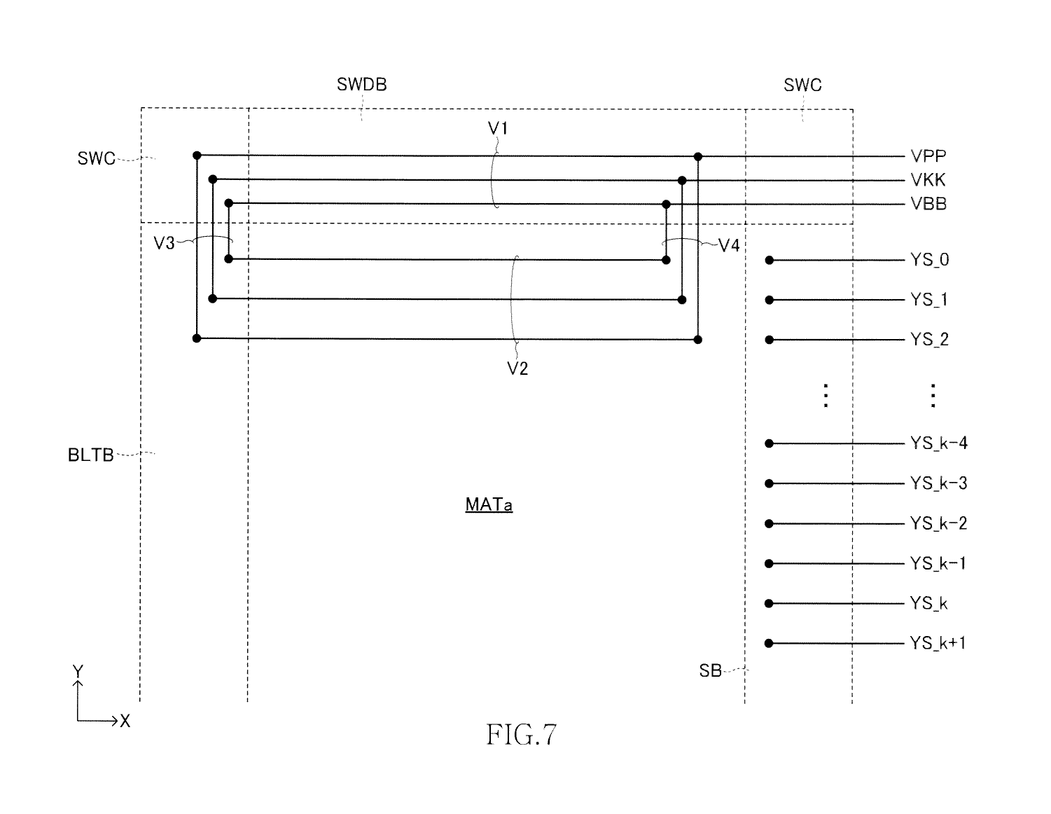

FIG. 7 is a diagram showing in more detail a region C shown in FIG. 5 according to the first embodiment of the present invention. Turning to FIG. 7, in the region C, in addition to the power-supply wirings V1 through which the power-supply potentials VPP, VKK, and VBB are supplied, auxiliary power-supply wirings V2 to V4 are provided. The auxiliary power-supply wirings V2 to V4 are short-circuited. The power-supply wirings V1 and the auxiliary power-supply wirings V3 and V4 are connected via through-hole electrodes that are so provided as to pass through corresponding wiring layers. Similarly, the auxiliary power-supply wirings V2 and the auxiliary power-supply wirings V3 and V4 are connected via through-hole electrodes that are so provided as to pass through corresponding wiring layers. The power-supply wirings V1 extend in the X-direction on the sub-word driver block SWDB. The power-supply wirings V1 exist even on other sub-word driver blocks SWDB that are not shown in FIG. 7. The second metal wiring layer M2 is used to layout the power-supply wirings V1.

The auxiliary power-supply wiring V2 are provided in the free spaces R1 or R2 shown in FIG. 5. On the memory mats MATa that are positioned in the end portion, the auxiliary power-supply wirings V2 extend in the X-direction. In the example shown in FIG. 7, on the wiring tracks on which the column selection lines YS_0 to YS_2 are formed, the auxiliary power-supply wirings V2 are formed. The free spaces R1 or R2 are positioned on the extended lines of the column selection lines YS or main input/output wirings MIO. Therefore, the auxiliary power-supply wirings V2 are formed on the fourth metal wiring layer M4.

The auxiliary power-supply wirings V3 are provided in the free spaces R3 shown in FIG. 5. On the bit-line termination blocks BLTB, the auxiliary power-supply wirings V3 extend in the Y-direction. That is, on the wiring tracks on which the sub-word selection lines FX are formed, the auxiliary power-supply wirings V3 are formed. The free spaces R3 are positioned on the extended lines of the sub-word selection lines FX. Therefore, the auxiliary power-supply wirings V3 are formed on the third metal wiring layer M3. The auxiliary power-supply wirings V3 are also designed to connect one end of the auxiliary power-supply wiring V2 to the power-supply wiring V1.

The auxiliary power-supply wirings V4 extend in the X-direction on the memory mats MATa, and are designed to connect the other end of the auxiliary power-supply wiring V2 to the power-supply wiring V1. The auxiliary power-supply wirings V4 are not formed in free space created by the configuration of the first embodiment. However, the layout of other wirings, such as the main word lines MWL, may be so designed as to create a space where the auxiliary power-supply wirings V4 will be formed.

According to the first embodiment, the auxiliary power-supply wirings V2 to V4 are provided. Therefore, on the memory mats MATa that are positioned in the end portion, the power supply is enhanced. As a result, it is possible to suppress a decline in potential and other troubles, which are likely to occur at the far ends of the power-supply wirings V1. Furthermore, the auxiliary power-supply wirings V2 and V3 can be formed in the free spaces R1 to R3. Therefore, the layout of other signal wirings, which are originally required, is not constrained.

As described above, according to the first embodiment, the power supply can be enhanced without practically constraining the layout of other signal wirings which are originally required.

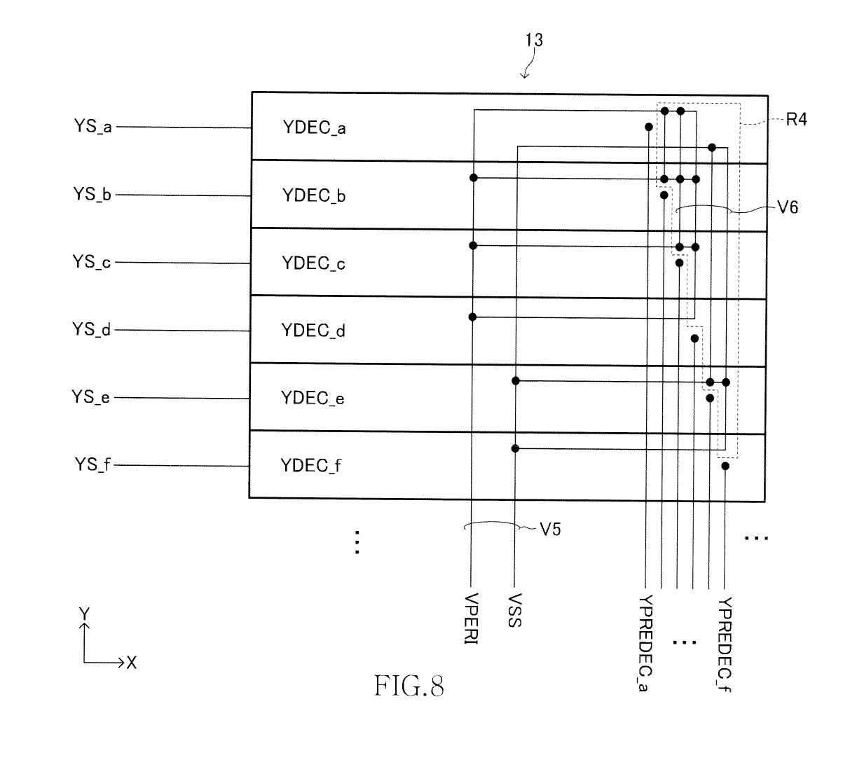

FIG. 8 is a diagram showing wirings connected to a column decoder according to a second embodiment of the present invention. The contents disclosed in FIGS. 1 to 6 may be identical to the second embodiment. The second embodiment of the present invention will be explained with reference to FIG. 8.

The column decoder 13 shown in FIG. 8 has a structure in which a plurality of decode blocks YDEC_a, YDEC_b, . . . are arranged in the Y-direction. Each of the decode blocks YDEC_a, YDEC_b, . . . is a functional block for activating the corresponding column selection lines YS_a, YS_b, . . . . Each of the decode block YDEC_a, YDEC_b, . . . is activated by an associated one of the pre-decode signals YPREDEC_a, YPREDEC_b, . . . . As shown in FIG. 8, the wirings that are used to supply the pre-decode signals YPREDEC_a, YPREDEC_b, . . . are so provided as to extend in the Y-direction. Therefore, there is no need to provide wirings beyond the corresponding decode blocks. That is, in the areas beyond the corresponding decode blocks, a free space R4 emerges on extended lines of the wirings.

According to the present embodiment, auxiliary power-supply wirings V6 are laid out in the free space R4. The auxiliary power-supply wirings V6 are electrically connected to power-supply wirings V5, which are used to supply power-supply potentials VPERI and VSS to the column decoder 13. In this manner, the power supply for the column decoder 13 is enhanced. In particular, a decline in power-supply potential is more likely to occur at the decode blocks that are closer to the far ends. However, according to the present embodiment, the functional blocks that are closer to the far ends have the enhanced power supply. Therefore, regardless of the layout position, an almost constant level of power-supply potential can be supplied.

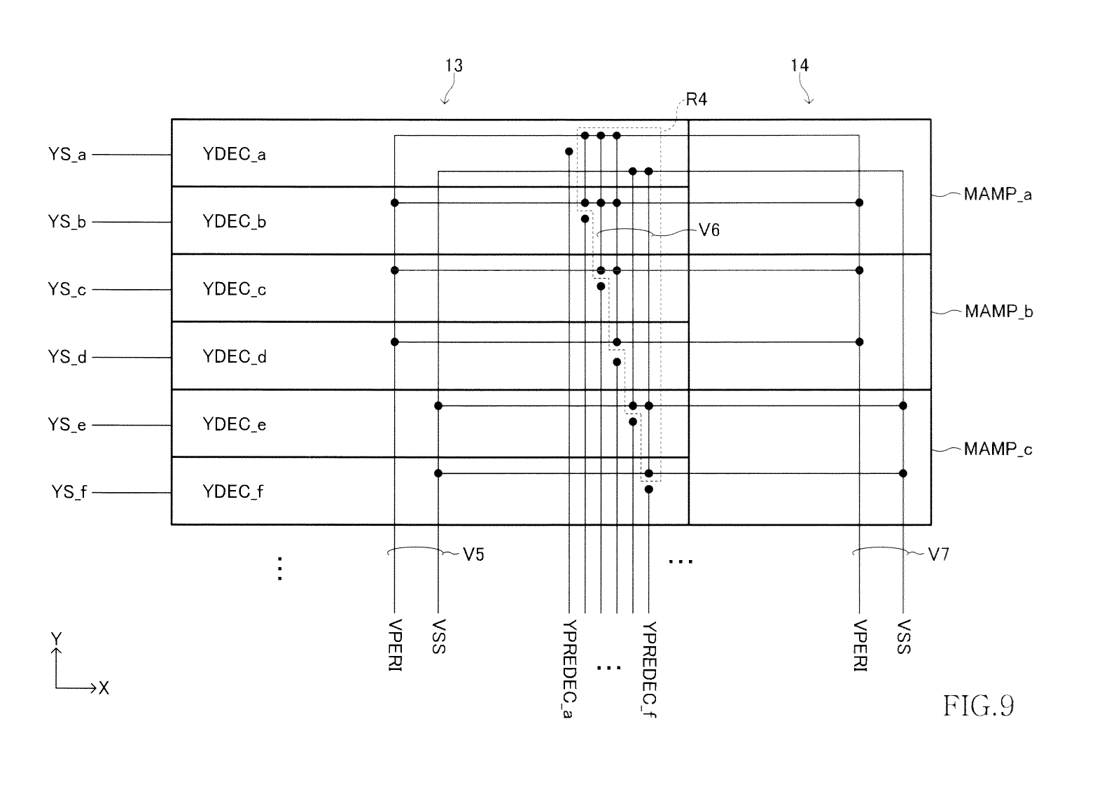

Incidentally, according to the layout shown in FIG. 2, the column decoders 13 are disposed away from the main amplifiers 14. However, the column decoders 13 may be disposed adjacent to the main amplifiers 14. In this case, as shown in FIG. 9, the auxiliary power-supply wirings V6 can be connected not only to the power-supply wirings V5, but also to power-supply wirings V7, which are used to supply power-supply potentials VPERI and VSS to the main amplifiers 14. As a result, the power supply for the column decoders 13, and the power supply for the main amplifiers 14 are enhanced. In the example shown in FIG. 9, a main amplifier 14 is divided into plurality of functional blocks MAMP_a, MAMP_b, . . . decline in power-supply potential is more likely to occur at the functional blocks that are closer to the far ends. However, according to the present embodiment, the functional blocks that are closer to the far ends have the enhanced power supply. Therefore, regardless of the layout position, an almost constant level of power-supply potential can be supplied.

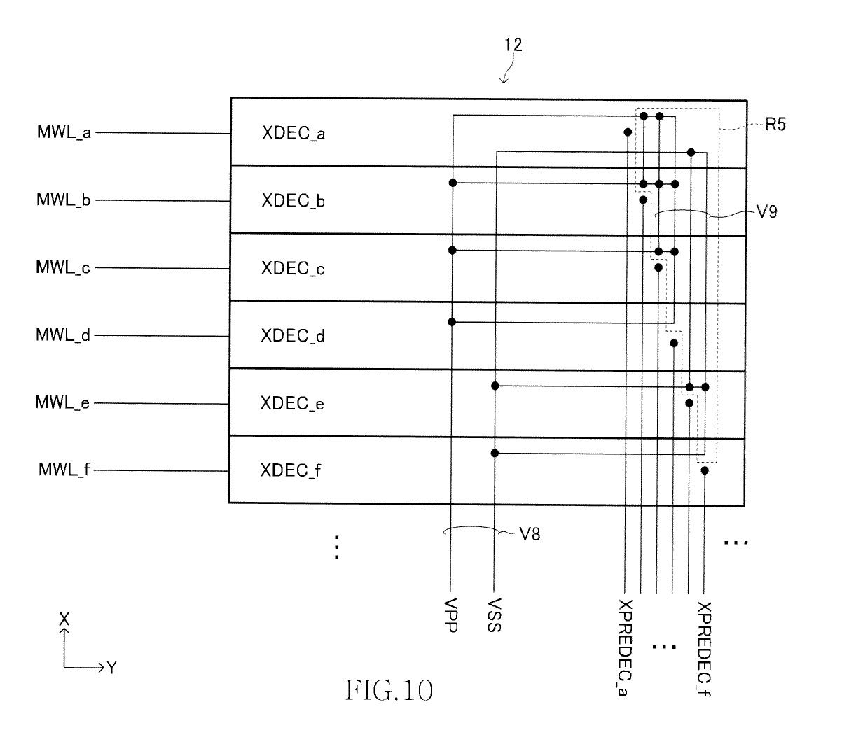

FIG. 10 is a diagram showing wirings connected to a row decoder according to a third embodiment of the present invention. The contents disclosed in FIGS. 1 to 6 may be identical to the third embodiment. The third embodiment of the present invention will be explained with reference to FIG. 10.

The row decoder 12 shown in FIG. 10 has a structure in which a plurality of decode blocks XDEC_a, XDEC_b, . . . are arranged in the X-direction. Each of the decode blocks XDEC_a, XDEC_b, . . . is a functional block for activating the corresponding main word lines MWL_a, MWL_b, . . . . Each of the decode blocks XDEC_a, XDEC_b, . . . is activated by an associated one of the pre-decode signals XPREDEC_a, XPREDEC_b, . . . . As shown in FIG. 10, the wirings that are used to supply the pre-decode signals XPREDEC_a, XPREDEC_b, . . . are so provided as to extend in the X-direction. Therefore, there is no need to provide wirings beyond the corresponding decode blocks. That is, in the areas beyond the corresponding decode blocks, a free space R5 emerges on extended lines of the wirings.

According to the present embodiment, auxiliary power-supply wirings V9 are laid out in the free space R5. The auxiliary power-supply wirings V9 are electrically connected to power-supply wirings V8, which are used to supply power-supply potentials VPP and VSS to the row decoder 12. In this manner, the power supply for the row decoder 12 is enhanced. In particular, a decline in power-supply potential is more likely to occur at the decode blocks that are closer to the far ends. However, according to the present embodiment, the functional blocks that are closer to the far ends have the enhanced power supply. Therefore, regardless of the layout position, an almost constant level of power-supply potential can be supplied.

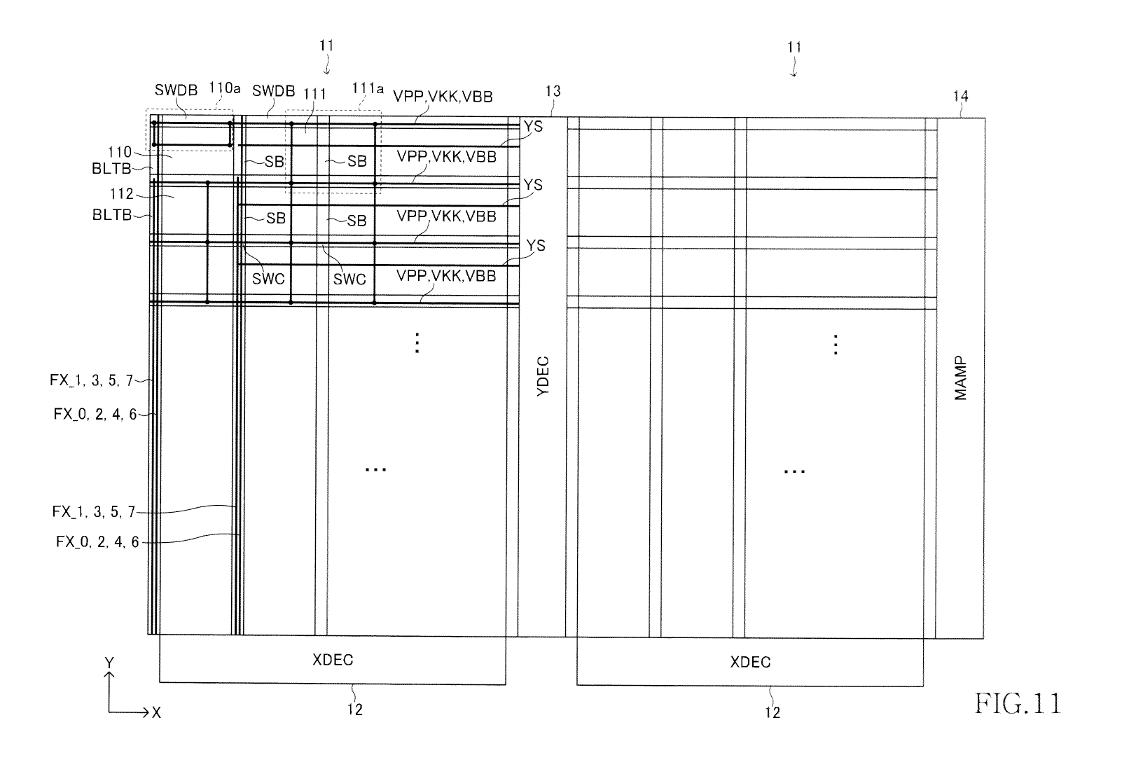

FIG. 11 shows an example of a wiring layout of power-supply wirings and auxiliary power-supply wirings according to a fourth embodiment of the present invention. The contents disclosed in FIGS. 1 and 7 may be identical to the fourth embodiment. The fourth embodiment of the present invention will be explained with reference to FIG. 11.

As described above in detail with reference to FIG. 7, a free space is provided on a memory mat MAT 110 which is positioned at a corner. The auxiliary power-supply lines are formed on the free space. The power-supply lines (VPP, VKK, and VBB) and the auxiliary power-supply lines are in a grid pattern or circular pattern when seen in planar view, as indicated by dashed line 110a. In a region where the power-supply lines and the auxiliary power-supply lines are formed, column selection lines YS do not cross the power-supply lines. Incidentally, for ease of explanation, the main input/output wirings MIO shown in FIG. 5 are not shown in FIG. 11.

Memory mats MAT 111 and MAT 112, which are adjacent to the memory mat MAT 110 at the corner, do not have the auxiliary power-supply lines (or the auxiliary power-supply lines V2, V3, and V4 shown in FIG. 7), which are provided in the memory mat MAT 110. As shown in FIG. 11, a power-supply line may be so provided as to connect one sub-word driver block SWDB, which is adjacent to the memory mats MAT 111 and MAT 112, to the other sub-word driver block SWDB. The power-supply line crosses a column selection line YS on the memory mat MAT 111. However, on the memory mat MAT 112, the power-supply line does not cross a column selection line YS.

As indicated by dashed line 111a, the power-supply lines may be formed into a grid pattern or circular pattern. The power-supply lines may be formed into a mesh pattern across the entire area of an array or in a portion thereof. As a result, regardless of a formation position thereof, power voltage can be supplied to each circuit in a stable manner.

On the memory mat MAT 112, the free space R2 shown in FIG. 5 may be utilized to provide an auxiliary power-supply line. Furthermore, by forming an auxiliary power-supply line in the free space R2 as shown in FIG. 7, the power supply may be enhanced.

On the memory mat MAT 111, a free space between the column selection lines YS may be utilized to provide an auxiliary power-supply line as shown in FIG. 7. In this case, by connecting an auxiliary power-supply line V3 shown in FIG. 7 to a power-supply line, the power supply may be enhanced.

The memory mat MAT 110 at the corner includes an auxiliary power-supply line for which the above-described free space is utilized. Moreover, a power-supply line may be so provided as to connect one sub-word driver block SWDB, which is adjacent to the memory mat MAT 110, to the other sub-word driver block SWDB. The above-described examples may be appropriately combined. The layout of an auxiliary power-supply line can be appropriately formed in accordance with power-supply characteristics required for products as long as free spaces of wiring tracks are utilized.

It is apparent that the present invention is not limited to the above embodiments, but may be modified and changed without departing from the scope and spirit of the invention.

For example, according to the above embodiments, what is described is an example in which the present invention is applied to the DRAM. However, the scope of application of the present invention is not limited to the DRAM. The present invention can also be applied to other semiconductor memory devices (flash memories, ReRAM, and the like), as well as to logic semiconductor devices such as processors.

What is claimed is:

1. A semiconductor device comprising:
a plurality of circuit blocks arranged in a first direction, the circuit blocks including a first circuit block that is positioned an end of the circuit blocks in the first direction;
a signal wiring arranged on a first layer and extending over the circuit block or blocks in the first direction so as to reach the first circuit block and produce a free space above the first circuit block,
the signal wiring being electrically connected to the first circuit block;
a power-supply wiring arranged on a second layer and extending over the circuit block or blocks in the first direction so as to reach the first circuit block,
the power-supply wiring supplying an operating voltage to the first circuit block; and
an auxiliary power-supply wiring being configured to enhance the operating voltage supplied by the power supply line, and
the auxiliary power-supply wiring being formed in the free space produced by the arrangement of the signal wiring.

2. The semiconductor device as claimed in claim 1, wherein the auxiliary power-supply wiring includes first, second, and third wirings, and first, second, third, and fourth contacts to enhance the operating voltage supplied by the power supply line,
the first wiring arranged on the first layer and extending above the first circuit block in the first direction;
the second and third wirings each arranged on a third layer and each extending above the first circuit block in a second direction, the first and second direction being perpendicular to each other,
the first contact connecting one end of the first wiring to one end of the second wiring,
the second contact connecting other end of the first wiring to one end of the third wiring,
the third contact connecting other end of the second wiring to the first power-supply wiring, and
the fourth contact connecting other end of the third wiring to the first power-supply wiring.

3. The semiconductor device as claimed in claim 1, wherein the first layer is lower in height than the second layer.

4. The semiconductor device as claimed in claim 1, wherein
each of the circuit blocks includes a memory mat having a plurality of memory cells and a sense block provided adjacent to the memory mat in the first direction, and
the free space is positioned on the memory mat included in the first circuit block.

5. The semiconductor device as claimed in claim 4, wherein the signal wiring is a column selection line used to select an associated one of a plurality of sense amplifiers included in the sense block.

6. The semiconductor device as claimed in claim 4, wherein the signal wiring is an input/output wiring operatively connected to an associated one of a plurality of sense amplifier included in the sense block.

7. The semiconductor device as claimed in claim 1, wherein
each of the circuit blocks includes a memory mat having a plurality of memory cells, a word driver block provided adjacent to the memory mat in the first direction, and a bit-line termination block provided adjacent to the memory mat in a second direction that is different from the first direction, and
the free space is positioned on the bit-line termination block included in the first circuit block.

8. The semiconductor device as claimed in claim 7, wherein the signal wiring is a word selection line used to select an associated one of a plurality of word drivers included in the word driver block.

9. The semiconductor device as claimed in claim 1, wherein
the circuit blocks are decode blocks, and
the signal wiring is used to supply a pre-decode signal that activates an associated one of the decode blocks.

10. The semiconductor device as claimed in claim 9, further comprising:
another circuit block provided adjacent to the decode blocks; and
another power-supply wiring supplying an operating voltage to the another circuit block,
wherein the auxiliary power-supply wiring is electrically connected to the another power-supply wiring.

11. A semiconductor device comprising:
first and second circuit blocks arranged in a first direction;
first and second wiring tracks each provided on the first and second circuit blocks and each extending in the first direction;
a first signal wiring supplying a first signal to the first circuit block, the first signal wiring being provided on the first wiring track on the first circuit block;
a first power-supply wiring supplying an operating voltage to the first circuit block, the first power-supply wiring being provided on the second wiring track on the first and second circuit blocks;
a first auxiliary power-supply wiring provided on the first wiring track on the second circuit block; and
second and third auxiliary power-supply wirings each extending in a second direction that crosses the first direction, the second and third auxiliary power-supply wirings being extending parallel to each other, each of the second and the third auxiliary power-supply wirings being electrically connected between the first power-supply wiring and the first auxiliary power-supply wiring on the second circuit block.

12. The semiconductor device as claimed in claim 11, wherein
the second circuit block is a memory mat including a plurality of memory cells, and
the first circuit block is a sense block including a plurality of sense amplifiers that amplify data read from the memory mat.

13. The semiconductor device as claimed in claim 12, further comprising:
a bit-line termination block arranged on an opposite side to the sense block with respect to the memory mat, wherein
the memory mat includes a plurality of bit lines and a plurality of dummy bit lines each extending in the first direction,
the bit lines are electrically connected to the sense amplifiers, and
the dummy bit lines are fixed to a predetermined potential in the bit-line termination block.

14. The semiconductor device as claimed in claim 11, wherein the first and second circuit blocks have substantially a same circuit configuration as each other.

15. The semiconductor device as claimed in claim 14, wherein the first circuit block is activated in response to the first signal.

16. The semiconductor device as claimed in claim 15, further comprising:
a third wiring track provided on the first and second circuit blocks, the third wiring track extending in the first direction; and
a second signal wiring supplying a second signal to the second circuit block, the second signal wiring being provided on the third wiring track on the first and second circuit blocks,
wherein the second circuit block is activated in response to the second signal.

17. The semiconductor device as claimed in claim 11, further comprising:
an second power-supply wiring supplying the operating voltage to an third circuit block, the second power-supply wiring being provided on a third wiring track that is different from the first and second wiring tracks;
fourth and fifth auxiliary power-supply wirings each extending in the second direction, the fourth and fifth auxiliary power-supply wirings being extending parallel to each other, each of the fourth and the fifth auxiliary power-supply wirings being electrically connected between the first power-supply wiring and the second power-supply wiring.

18. The semiconductor device as claimed in claim 11, further including
a memory array defined by a corresponding x decoder and a corresponding y decoder, the memory array including the first and second circuit blocks;
a voltage generating circuit generating the operation voltage to be supplied to the first power-supply wiring; and
wherein the second circuit block is positioned at a first corner of the memory array, the first corner being a farthest corner, among corners of the memory array, from the voltage generating circuit.
